(19) United States
(12) Patent Application Publication
(10) Pub. No.: US 2014/0197817 A1
(43) Pub. Date: Jul. 17, 2014

(54) Current Probe, Current Probe Measurement System, and Current Probe Measurement Method

(71) Applicants: Hiroki Funato, Tokyo (JP); Takashi Suga, Tokyo (JP)

(72) Inventors: Hiroki Funato, Tokyo (JP); Takashi Suga, Tokyo (JP)

(73) Assignee: Hitachi, Ltd., Chiyoda-ku, Tokyo (JP)

(21) Appl. No.: 14/232,758

(22) PCT Filed: Jul. 20, 2012
(86) PCT No.: PCT/JP2012/068406

§ 371 Date: Jan. 14, 2014

(30) Foreign Application Priority Data
Sep. 29, 2011 (JP) 2011-213708

(51) Int. Cl. G01R 19/00

(52) U.S. Cl. CPC G01R 19/0092
USPC 324/149

(57) ABSTRACT

Provided is a current probe which reduces, in current measurement, a measurement error due to an unnecessary magnetic field generated from a subject not to be measured, said subject being adjacent to a subject to be measured. The current probe is characterized in having: a sensor that detects a magnetic field; a transmission path connected to the sensor; and a pair of conductive members, which protrude toward the front from a leading edge portion of the sensor, and are provided to face the sensor. The current probe is also characterized in that a front portion of the sensor, said portion being surrounded by the protruding portions of the conductive members, is opened in the direction of a plane that faces the conductive members.

### TECHNICAL FIELD

The present invention relates to a current probe.

### BACKGROUND ART

As a background art of the present technical field, patent literature 1 (JP-A-2000-214200) is disclosed. In this patent literature 1, there is disclosed a structure in which “about a neighboring magnetic field probe composed of a loop coil and a transmission line, a conductive member covers the whole in one body with an opening provided at a tip coil side of a detector, or about a neighboring magnetic field probe with a conductive member covering the whole nearly up to the tip coil in one body, the tip coil is installed on an installing plane and the gap between this plane and the conductive member matches the spacing of objects to be measured”.

### CITATION LIST

### Patent Literature

Patent Literature 1: JP-A-2000-214200

### SUMMARY OF INVENTION

### Technical Problem

In recent years, an EMC (Electro-Magnetic Compatibility) design development in electronic equipment is emphasized. In the countermeasures, a sensor or a probe is absolutely essential as a way of visibly measuring electromagnetic waves. Further, along with complexity or miniaturization of electronic equipment structures, an object to be measured becomes diversified and an improvement in local measurement accuracy is requested.

When a part of a plurality of connector pins or harnesses arranged in parallel on a substrate are set to an object to be measured, for example, a current is generated in a member adjacently arranged in a member to be measured. In this case, there arises a problem that an unnecessary magnetic field is generated and detection sensitivity of a magnetic field generated by a current flowing through the object to be measured is reduced due to an influence of interference of this unnecessary magnetic field.

In patent literature 1, there is illustrated a structure in which when a loop coil type magnetic field sensor is covered by using a conductive member and an opening is provided in a tip, an unnecessary induced voltage due to a surrounding environment electromagnetic field is reduced. Suppose, however, that in this structure, the magnetic field sensor is covered by using a conductive member so as to shield a surrounding electromagnetic field. In this case, not only the surrounding electromagnetic field but also a magnetic field generated by an object to be measured is almost shielded other than a magnetic field invaded from the opening provided in the tip. Accordingly, an improvement in a width of magnetic field detection sensitivity as a signal-to-noise ratio is extremely small.

Further, when the magnetic field sensor is covered by a conductive member so that a magnetic field generated by the object to be measured is sufficiently detected, an influence of interference of an unnecessary magnetic field generated around the object to be measured becomes large. As a result, an improvement in a width of the magnetic field detection sensitivity as a signal-to-noise ratio becomes extremely small.

Further, the probe disclosed in patent literature 1 has a structure in which a loop coil is formed by making prints on a flat plate such as a printed-circuit board. Accordingly, when a current flowing through a connector pin or a harness is measured, a position of the probe is hard to be determined with respect to the connector or the harness. Therefore, displacement of the probe to the object to be measured directly causes reduction in current detection accuracy.

In view of the foregoing, it is an object of the present invention to provide a current probe that reduces a measurement error due to an influence of an unnecessary magnetic field generated by an object not to be measured adjacent to an object to be measured in a current measurement.

### Solution to Problem

To solve the above-described problems, a configuration described in the scope of claims, for example, is adopted.

The present application includes a plurality of ways of solving the above-described problems and one example thereof is quoted. A current probe includes a sensor that detects a magnetic field, a transmission line that is connected to the sensor, and a pair of conductive members that projects to a forward direction from a tip of the sensor and that is provided so as to face the sensor, wherein a front portion of the sensor, which is surrounded by a projecting portion of the conductive members, is opened in a direction of a plane that faces the conductive members.

### Advantageous Effects of Invention

According to the present invention, there is reduced a measurement error due to an influence of an unnecessary magnetic field generated by an object not to be measured adjacent to an object to be measured in the current measurement.

Other objects, configurations, and advantages of the invention will become apparent from the following description of the embodiments.

### BRIEF DESCRIPTION OF DRAWINGS

FIG. 1 is a configuration diagram illustrating a measurement system using a current probe;

FIG. 2 is a perspective view illustrating the current probe of a first embodiment;

FIG. 3 illustrates a measurement principle of the current probe;

FIG. 4 illustrates a principle of a measurement error exerted by an unnecessary magnetic field;

FIG. 5 is a structure diagram illustrating a conventional current probe;

FIG. 6(a) is a side view at the time of measuring a current by using the current probe of the first embodiment;

FIG. 6(b) is a top view at the time of measuring a current by using the current probe of the first embodiment;

FIG. 7 is a graph illustrating a frequency characteristic of an unnecessary induced voltage in the current probe of the first embodiment and the conventional current probe;

FIG. 8 is a schematic diagram illustrating displacement to an object to be measured of the current probe;

FIG. 9 is a graph illustrating a displacement amount and a measurement error to the object to be measured of the current probe;

FIG. 10 is a structure diagram illustrating the current probe of a second embodiment;

FIG. 11(a) is a top view illustrating the current probe of a third embodiment;

FIG. 11(b) is a side view viewed in an x-x′ direction of the current probe of the third embodiment;

FIG. 12 is a structure diagram illustrating the current probe of a fourth embodiment;

FIG. 13 is a configuration diagram in which a transmission line is bent in the current probe of the present invention; and

FIG. 14 is a configuration diagram illustrating a measurement system using the current probe of the present invention in which the transmission line is bent.

### DESCRIPTION OF EMBODIMENTS

Hereinafter, embodiments of a current probe according to the present invention will be described with reference to the accompanying drawings.

### First Embodiment

In the present embodiment, an example of a probe capable of measuring a current flowing through a pin or a harness with high accuracy and high sensitivity will be particularly described. Further, a case of a connector pin that is mounted on a substrate of electronic equipment will be described as an object to be measured. However, the object is not limited to a connector pin, and a probe is applicable also to an object at which a plurality of line currents are concentrated such as a harness, or other objects to be measured.

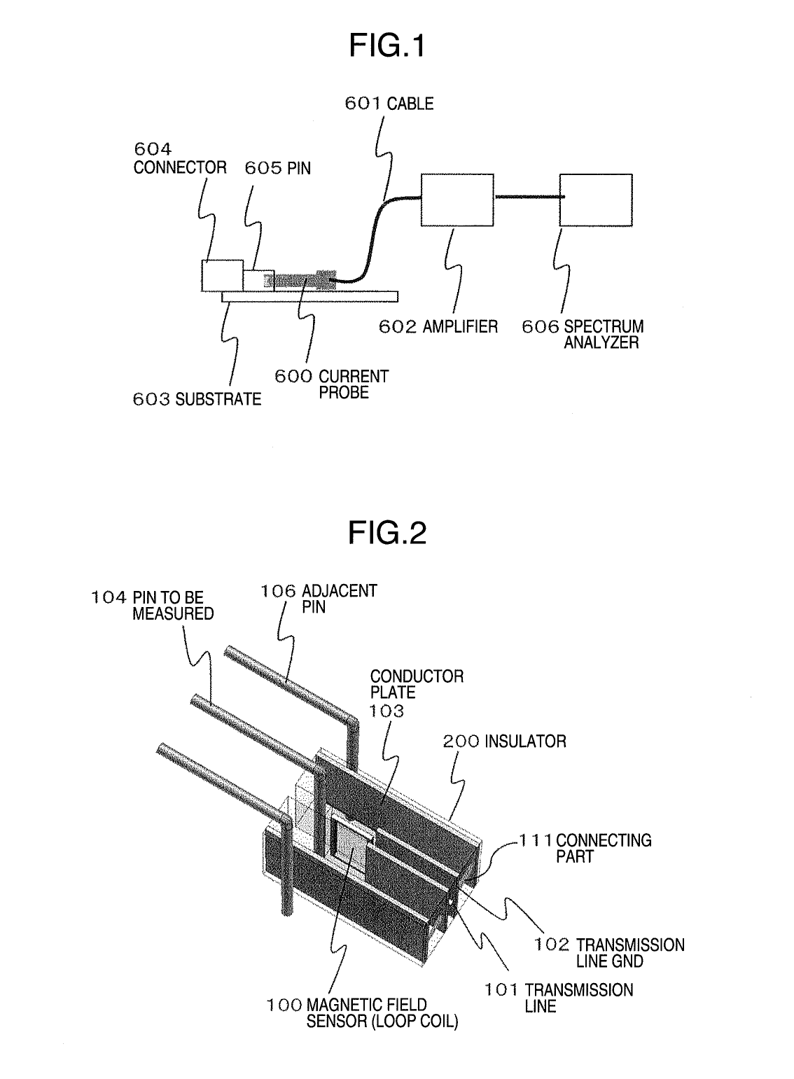

FIG. 1 illustrates an example of a measurement system configuration diagram using a current probe of the present embodiment. The current probe 600 is connected to a spectrum analyzer 606 being a measurement instrument via a cable 601 and an amplifier 602. In FIG. 1, the current probe 600 is approximated to a pin 605 being an object to be measured of a connector 604 that is mounted on a substrate 603 and a current is measured. A measurement principle will be described later. Further, the amplifier 602 may be preferably used, if necessary. The spectrum analyzer 606 is generally used as a measurement instrument, and further an oscilloscope may be used.

FIG. 2 is a perspective view illustrating a configuration figure of the current probe according to the present embodiment. As illustrated in FIG. 2, the current probe of the present embodiment is configured by including a magnetic field sensor 100, a transmission line 101, a transmission line GND 102, and a conductor plate 103. The magnetic field sensor 100 of the present embodiment includes a loop coil, and connected to the transmission line 101 for transmitting induced voltage generated at the loop coil to a measurement instrument. In the sensor that detects a magnetic field and converts it to a voltage or a current, the loop coil has an advantage that it is easily manufactured while having high sensitivity to high-frequency magnetic field. Note that the magnetic field sensor may be configured by using a Hall element regardless of the loop coil.

The transmission line 101 is adapted to a microstrip line structure or a strip line structure. The microstrip line or the strip line structure is hard to receive an influence of a surrounding magnetic field, and therefore a detection error due to an unnecessary magnetic field is further reduced. Further, the transmission line 101 is preferably designed so as to have characteristic impedance suited to impedance of a cable to be connected or that of a measurement instrument.

An effect is exerted that the transmission line GNDs 102 facing each other are arranged on both sides of this transmission line 101 and the amount of the surrounding electromagnetic field connected to the transmission line 101 is reduced due to this structure.

The conductor plate 103 is arranged so as to face the magnetic field sensor 100 at the outside of the transmission line GND 102, namely, at the side opposite to the transmission line 101 side. At the same time, the conductor plate 103 is arranged so as to project to a forward direction from a tip of the magnetic field sensor 100, namely, a tip side direction of the current probe. In the present embodiment, as illustrated in FIG. 2, the conductor plate 103 is arranged so as to project to a direction of an opposite side to a connection side between the magnetic field sensor 100 and the transmission line 101. Further, the conductor plate 103 is connected to the transmission line GND 102 via a connecting part 111.

When the conductor plate 103 is connected to the transmission line GND 102, a potential of the conductor plate 103 is the same as that of the transmission line GND 102. Therefore, an unnecessary induced voltage generated on the conductor plate due to potential fluctuations of a pin approximated to the conductor plate 103, namely, a noise component in a measurement of a magnetic field is reduced. A conductor such as copper may be preferably used as the conductor plate 103, and further even a material such as ferrite having high permeability and low electric conductivity may be used in addition to a conductor. In the case of a magnetic body, an unnecessary magnetic field generated by an adjacent pin current is concentrated in the magnetic body, and fails to leak to the magnetic field sensor side. Therefore, in the same manner as in the case of using a conductor having high electric conductivity, an effect of reducing an influence of an unnecessary magnetic field on the magnetic field sensor is obtained.

As illustrated in FIG. 2, the structure in which the magnetic field sensor 100, the transmission line 101, the transmission line GND 102, and the conductor plate 103 are connected in one body as in the above-described configuration. These structure bodies are covered with an insulator 200 such as resin so that the loop coil and the conductor plate 103 are not contacted with the pin to be measured. At least the loop coil and the conductor plate 103 are preferably covered with the insulator 200.

Further, in the tip of the current probe of the present embodiment, the conductor plate 103 projects to a tip direction of the current probe from the magnetic field sensor 100. The tip of the magnetic field sensor 100 has an opened shape in a direction of a plane facing the conductor plate 103 so that an object to be measured is inserted into the inside of the projecting conductor plate 103, namely, the magnetic field sensor 100 side for measurement. The tip of the current probe of the present embodiment has a concave structure as illustrated in FIG. 2, for example. Through this structure, when the pin to be measured is inserted into a concave portion of the probe tip and measured, the conductor plate is inserted between a pin to be measured and an adjacent pin not to be measured. Therefore, an influence of an unnecessary magnetic field generated at the pin not to be measured is reduced and a measurement error of an object to be measured is reduced.

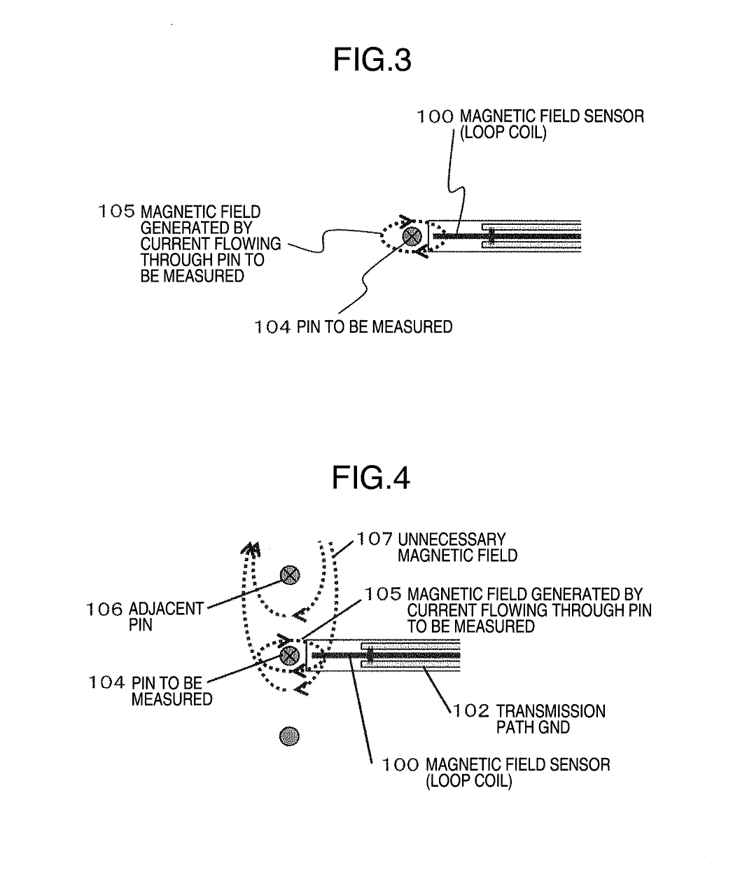

Next, a principle in which the current probe measures a current flowing through the pin to be measured 104 will be described with reference to FIG. 3. Further, a principle in which the conductor plate 103 reduces an influence of an unnecessary magnetic field generated by a current flowing through the adjacent pin will be described with reference to FIG. 4.

First, when a current flows through the pin to be measured 104 as illustrated in FIG. 3, a magnetic field 105 is generated around the pin. To measure this magnetic field 105, the magnetic field sensor 100 of the current probe is installed for measurement so as to be approximated to the pin to be measured 104. A part of the magnetic field 105 generated by a current flowing through the pin to be measured 104 at this time is interlinked with the loop coil being the magnetic field sensor 100, and the induced voltage is induced on both ends of the loop coil. Intensity and a phase of this induced voltage are measured by using a measurement instrument such as the spectrum analyzer 606. A voltage is reduced to a magnetic field and the magnetic field is reduced to a current, and thereby intensity and a phase about a value of the current flowing through the object to be measured are acquired. When an area of the loop coil, a frequency, a permeability, and a magnetic field to be interlinked with the loop coil are set to S (m2), f (Hz), and H (A/m), respectively, a voltage Vh (V) induced on the loop coil is represented by formula (1).

Vh=2·π·f·μ·S·H (Formula 1)

Further, when a plurality of pins except the pin to be measured are arranged in parallel as illustrated in FIG. 4, a current flows through a pin adjacent to the pin to be measured. Accordingly, a magnetic field is generated by this current around the adjacent pin 106. Also, a part of a magnetic field generated by the current flowing through the adjacent pin is interlinked with the loop coil in the same manner and an unnecessary induced voltage is generated, and thereby an error is caused.

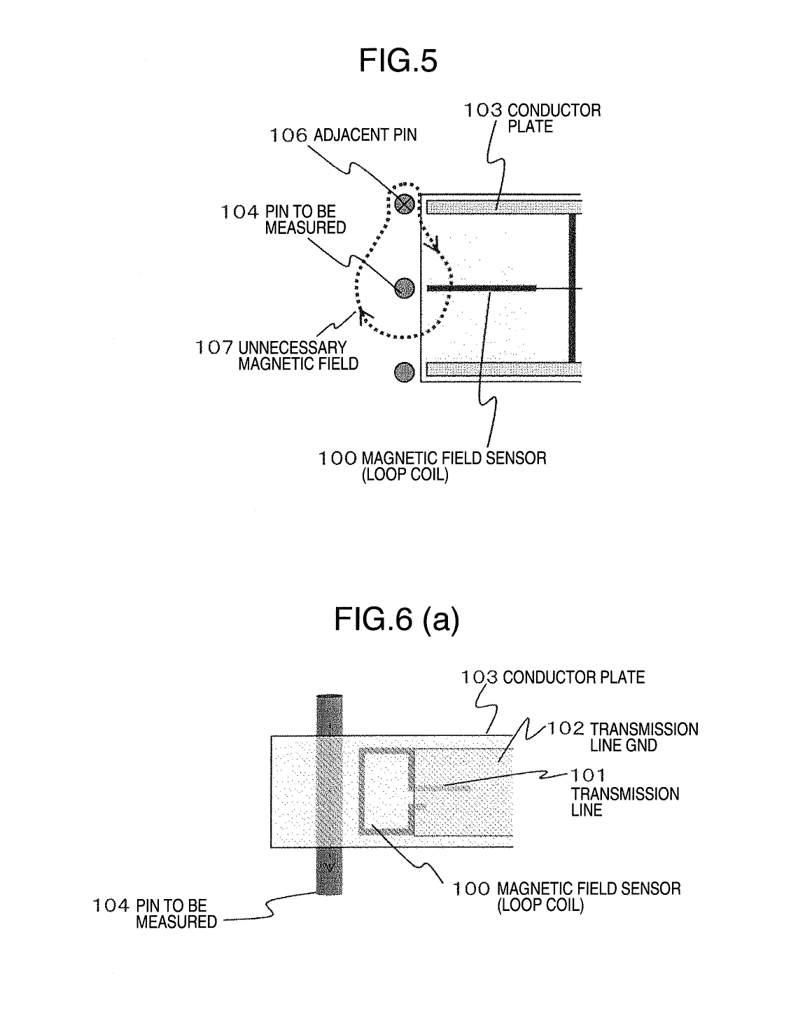

A structure of a conventional current probe is illustrated in FIG. 5. The conventional probe has a structure in which a magnetic field sensor and a conductor plate are arranged so as to face each other at the same position in a tip direction. An unnecessary magnetic field 107 generated at an adjacent pin at this time has an orbit as illustrated in FIG. 5. Therefore, a magnetic field incapable of being canceled by the conductor plate is interlinked with the magnetic field sensor 100, and as a result an influence is received in the current measurement.

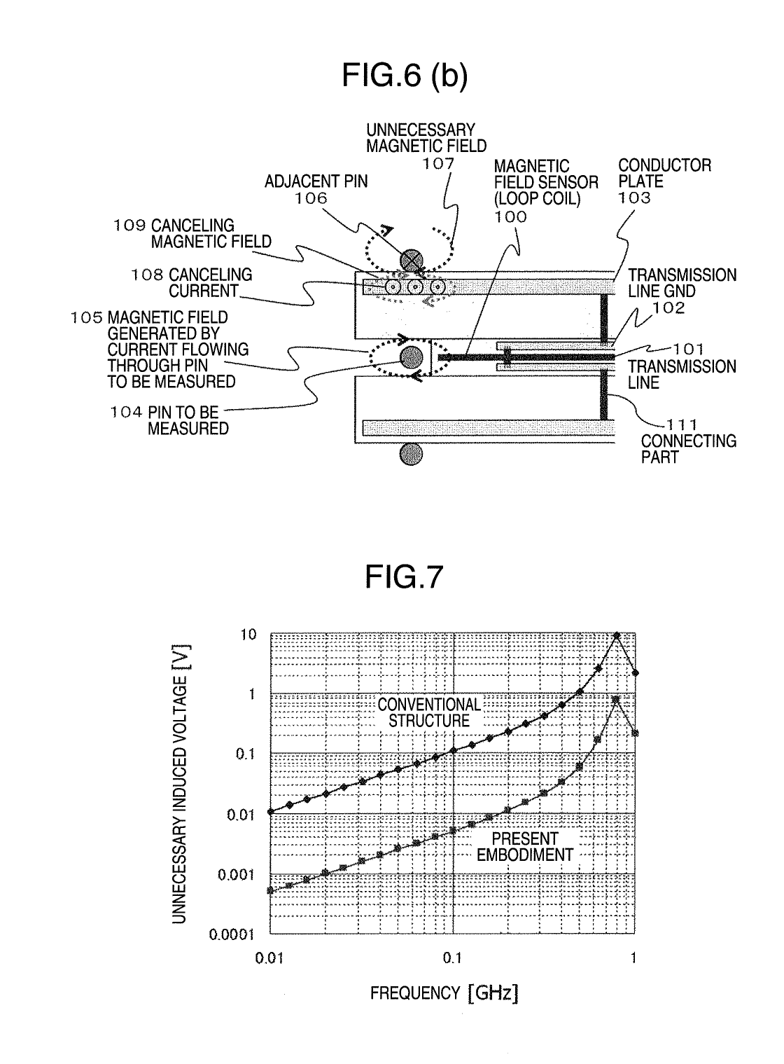

As compared to the above, in a magnetic field measurement using the current probe of the present embodiment, as illustrated in FIGS. 6(a) and 6(b), the current probe of the present embodiment is installed so that the pin to be measured 104 is first inserted between the projecting conductor plates 103, namely, into a concave portion of the tip of the current probe. FIG. 6(a) is a side view illustrating a configuration at the time of measuring a pin current by using the current probe of the present embodiment, and FIG. 6(b) is a top view illustrating a configuration at the time of measuring a pin current by using the current probe of the present embodiment.

In the structure of the current probe of the present embodiment, the conductor plate 103 that projects to the outside from the transmission line GND 102 and further to the tip direction of the probe from the loop coil is arranged between the adjacent pin 106 and the pin to be measured 104 so as to project to the tip direction of the probe from a segment connecting the pin to be measured 104 and the adjacent pin 106. Further, when the conductor plate 103 is arranged in the vicinity of the adjacent pin 106, a canceling current 108 flows through the conductor plate 103 in a direction opposite to that of a current flowing through the adjacent pin and a magnetic field 109 is generated in a direction of canceling the unnecessary magnetic field 107 so as to cancel the unnecessary magnetic field 107 generated by a current flowing through the adjacent pin 106. Thereby, an unnecessary interlinked magnetic field and induced voltage generated on the loop coil by a current flowing through the adjacent pin are reduced.

For the purpose of enlarging a canceling effect of the unnecessary magnetic field, the current probe needs to have a structure in which the conductor plate 103 projects to at least the tip direction of the probe from the magnetic field sensor 100. Further, in the canceling effect of a magnetic field due to the adjacent current, as a distance between the conductor plate 103 and the adjacent pin 106 is shorter, the canceling effect becomes larger. The reason is that as the distance is shorter, the canceling current 108 that is induced on the conductor plate 103 by a current flowing through the adjacent pin 106 becomes larger, and further, as the canceling current 108 is more approximated to a size of the current flowing through the adjacent pin 106, the magnetic field 109 generated by the canceling current 108 becomes larger.

Further, in order that a magnetic field generated by a current flowing through the adjacent pin may be prevented from being interlinked with the loop coil, a size of the conductor plate 103 in a height direction is preferably larger than or equal to a size of the loop coil in the same direction. In addition, the conductor plate may be preferably enlarged in the range where controllability of the measurement is not impaired with respect to a size of the object to be measured. The reason is that a surrounding unnecessary magnetic field that invades as a route the insulator provided between the conductor plate and the loop coil and is interlinked with the loop coil is reduced as much as possible.

Further, a thickness of the conductor plate 103 is preferably made thicker than a skin depth to a material of the conductor plate 103 in a lowest frequency in a measurement frequency range. Thereby, in the case of canceling the magnetic field 105 generated by the current flowing through the adjacent pin 106, the canceling effect is obtained in the state where an influence of loss due to thinning of the conductor plate is minimized even if the canceling current flows through a skin of the conductor plate 103.

An effect of reducing the unnecessary magnetic field in the case of using the current probe of the present embodiment will be described as compared to a case of using the conventional current probe. Here, a measurement state of using the conventional current probe is illustrated in FIG. 5, and a measurement state of using the current probe of the present embodiment is illustrated in a top view of FIG. 6(b).

In the current probe structure of a conventional technology as illustrated in FIG. 5, the conductor plate is provided to cover the transmission line GND or the sensor section of the probe. Therefore, a tip of the current probe has a flat structure through a positional relationship between the magnetic field sensor 100 and the conductor plate 103. On the other hand, as illustrated in the top view of FIG. 6(b), the current probe of the present embodiment has a structure in which the conductor plate 103 that projects to the tip direction from the loop coil is provided and the tip has a concave shape so as to cancel the unnecessary magnetic field generated by the current flowing through the adjacent pin 106. About the respective structures, an induced voltage onto the current probe at the time when a current flows through the adjacent pin is calculated by analyzing an electromagnetic field for comparison.

FIG. 7 illustrates an example of a result where a frequency characteristic of the induced voltage due to a magnetic field generated by the adjacent pin current is calculated by analyzing an electromagnetic field about the current probe of the present embodiment and the probe of the conventional technology. A horizontal axis represents frequencies, and a vertical axis represents results in which an induced voltage onto the probe due to the unnecessary magnetic field generated by a current flowing through the adjacent pin is analyzed in the range of 10 MHz to 1 GHz. It indicates that in the whole frequency range, the unnecessary induced voltage in the structure of the present embodiment is reduced to 1/10 or less as compared to the unnecessary induced voltage in the structure of the conventional technology. In FIG. 7, results up to 1 GHz are illustrated; further, since a reduction mechanism of the unnecessary induced voltage is not depending on frequencies, the same effect is obtained also in 1 GHz or more.

The current probe of the present embodiment has a structure in which a position of the magnetic field sensor is easily fixed to a current flowing through the object to be measured while realizing a structure in which the unnecessary magnetic field generated by a current adjacent to a current flowing through the object to be measured is canceled. Next, the above-described structure will be described.

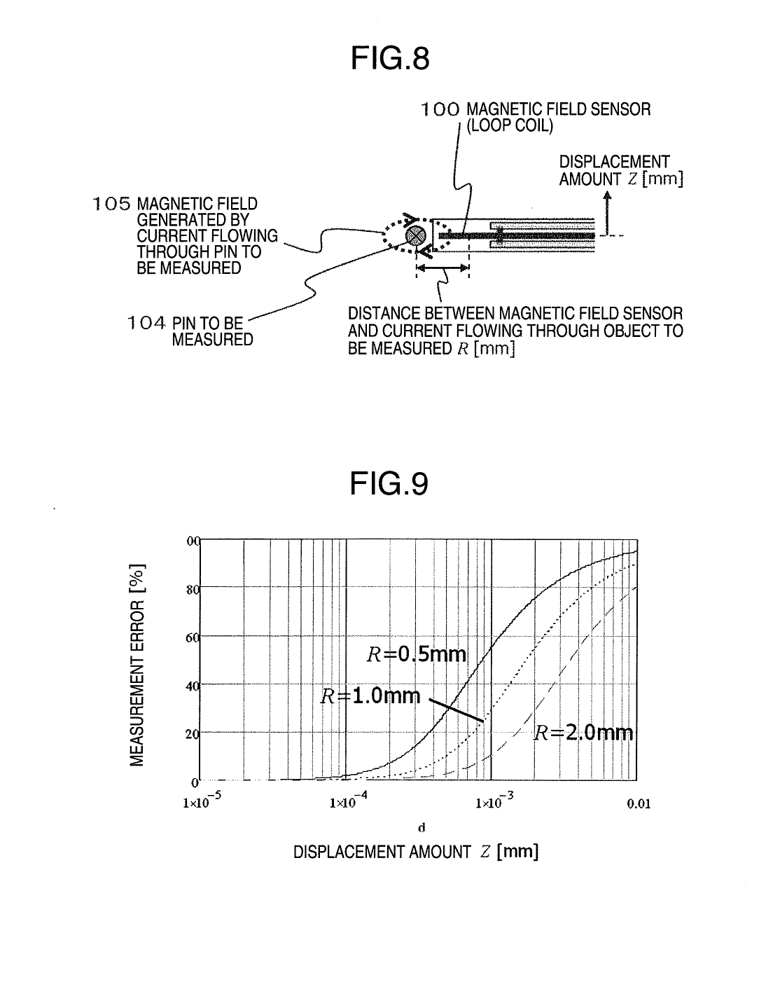

FIG. 8 is a schematic diagram of displacement to the object to be measured of the current probe. FIG. 9 is a graph illustrating a displacement amount and a measurement error to the object to be measured of the current probe, and illustrates conditions and results where how much error is caused is calculated to the displacement amount Z (mm) of the probe. As illustrated in FIG. 8, a distance between the pin to be measured 104 and a central position of the magnetic field sensor 100 is set to R (mm), and the displacement amount in the horizontal direction of the magnetic field sensor to the pin to be measured 104 is set to Z (mm). In the above-described conditions, results of the measurement error to the displacement amount Z are as illustrated in the graph of FIG. 9.

Suppose that as illustrated in FIG. 9, a distance R (mm) between a central position of the magnetic field sensor 100 and a current flowing through the object to be measured is set to 0.5 mm. In this case, FIG. 9 indicates that when a probe position is displaced by 1 (mm), an error is 50% or more, and displacement of the probe exerts a large influence on the measurement error.

The probe of the present embodiment has a structure in which the conductor plate 103 that is arranged so as to face the magnetic field sensor 100 projects to the tip direction of the probe, namely, the direction of the object to be measured from the magnetic field sensor 100 and the tip of the probe has a concave shape. Therefore, since the object to be measured and the magnetic field sensor are fixed by aligning a position therebetween so as to insert a pin to be measured into this concave portion, the measurement error due to this displacement is reduced.

Further, the magnetic field sensor 100, the transmission line 101, and the conductor plate 103 for canceling an unnecessary magnetic field generated by an adjacent current are easily manufactured by configuring them each by using a printed-circuit board. On this occasion, each substrate may be a single-piece substrate, or separate substrates may be connected by using solder. In addition, a configuration using a printed-circuit board is not limited to the present embodiment, and further applicable also to other embodiments.

### Second Embodiment

In the present embodiment, a structure example of the probe in which an effect of reducing a measurement error due to an unnecessary magnetic field generated by a current flowing through an object not to be measured adjacent to a current flowing through an object to be measured is improved will be described.

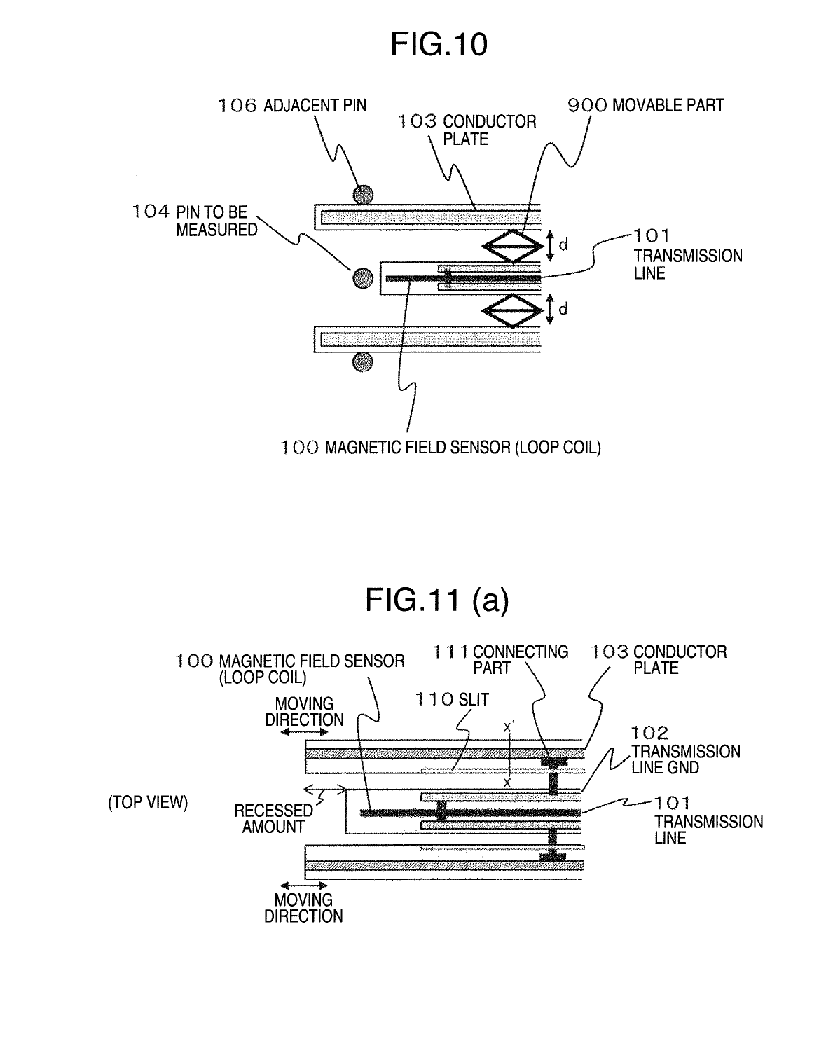

FIG. 10 illustrates an example of a structure diagram of the current probe according to the present embodiment. The current probe of the present embodiment includes the magnetic field sensor 100 that detects a magnetic field, the transmission line 101 that is connected to the magnetic field sensor, the transmission line GND 102, and the conductor plate 103 for canceling an unnecessary magnetic field generated by a current flowing through an adjacent pin. Further, the conductor plate 103 is connected to the transmission line GND 102 by using a movable part 900 that is adjustable in a width direction of the current probe. In this manner, when a position of the conductor plate 103 is moved, the conductor plate 103 is arranged near by the adjacent pin even under conditions that a distance between a pin or harness to be measured through which a current flows and an adjacent pin or harness is different from each other.

As an example of the movable part 900, an elastic body member is included. Here, a structure using a spring as an example of the elastic body member will be described. As this spring, a spring is selected that a length d in the state where the spring is stretched is longer than a distance between an object to be measured and an object which generates an unnecessary magnetic field. Thereby, in the state where the spring is pressed, the conductor plate 103 is inserted between the pin to be measured 104 and any one of the adjacent pins 106 arranged adjacently on both sides. Further, a force acts that when a force for pressing the spring is weakened, it is stretched, namely, a force acts in a direction in which the adjacent pin 106 is separated from the pin to be measured 104 in the center by two pieces of the conductor plates 103. As a result, the conductor plate 103 is pressed against the adjacent pin 106.

As in this example, when a distance between the magnetic field sensor 100 and any one of the conductor plates 103 provided on both sides is varied, the unnecessary magnetic field reduction effect is obtained without manufacturing the probe again with respect to various objects to be measured. In addition, when the conductor plates 103 provided on both sides of the magnetic field sensor 100 for measurement are arranged near by a current being a source for generating an adjacent unnecessary magnetic field, the unnecessary magnetic field reduction effect is improved. Further, by using a force for pressing the spring being the movable part 900 for connecting the transmission line GND 102 and the conductor plate 103, the pin to be measured is inserted and pinched in a concave portion included in the current probe of the present invention. Thereby, a position of the current probe is easily fixed and a measurement error due to displacement of the magnetic field sensor of the current probe is reduced.

Further, in accordance with a distance between the pin to be measured 104 and the adjacent pin not to be measured 106, a structure in which springs having different sizes and elastic forces are used at the conductor plates 103 of right and left may be used.

In the present embodiment, the movable part 900 is described by, as an example, using the spring being the elastic body member. Further, when a connecting member and a mechanism in which the conductor plate is movable so as to adjust a distance between the magnetic field sensor and the conductor plate in accordance with a distance between the pin to be measured and the adjacent pin not to be measured, other configurations may be used regardless of the spring or the elastic body member.

### Third Embodiment

In the present embodiment, a structure example of the probe in which sensitivity for detecting a magnetic field generated by a current flowing through the object to be measured is improved will be described.

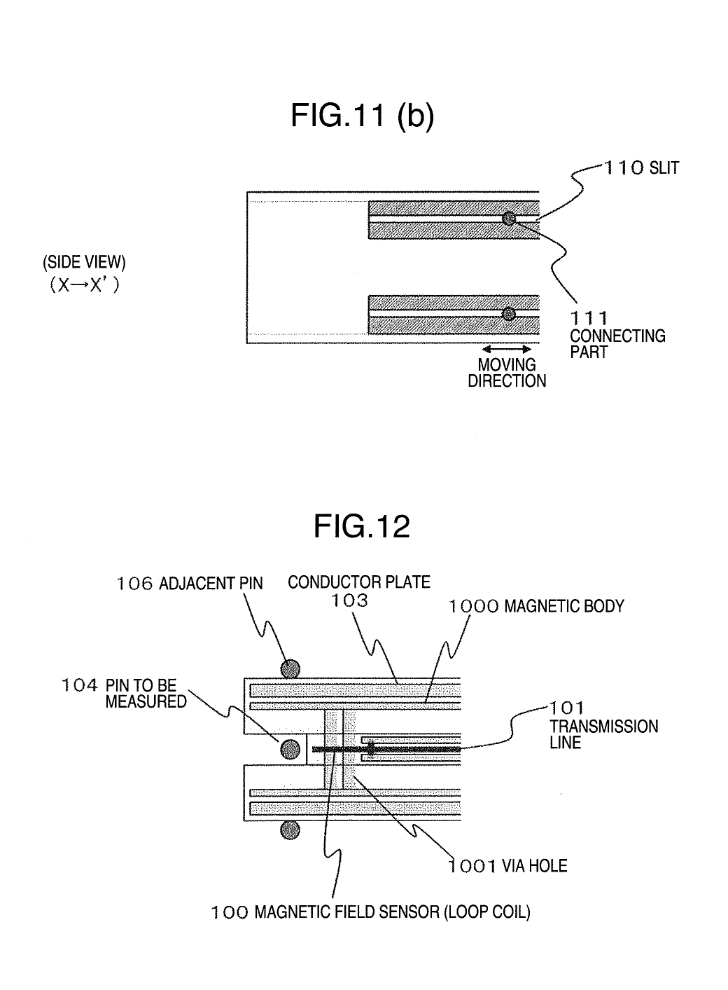

FIGS. 11(a) and 11(b) each illustrate an example of a structure diagram of the current probe according to the present embodiment. The current probe of the present embodiment includes the magnetic field sensor 100 that detects a magnetic field and converts it to a voltage, the transmission line 101 that is connected to the magnetic field sensor 100, the transmission line GNDs 102, and the conductor plates 103 for canceling an unnecessary magnetic field generated by a current flowing through the adjacent pin. Further, FIGS. 11A and 11B each illustrate an example where the conductor plate 103 is connected to the transmission line GND 102 by using a moving mechanism that is adjustable in a length direction of the current probe. In the moving mechanism having the conductor plate in the length direction to be described in the present embodiment, there is illustrated a configuration example in which slits are provided in the conductor plate substrates and the conductor plate substrates are slid and movable.

FIG. 11(a) is a top view of the current probe according to the present embodiment. The magnetic field sensor 100 is connected to the transmission line 101, and the transmission line GNDs 102 are arranged so as to face each other at the outside of the transmission line 101. Further, at the outside of the transmission line 101, the conductor plate substrates each having the conductor plate 103 are arranged so as to face the magnetic field sensor 100. Further, the slits 110 are provided in the conductor plate substrates, and the connecting parts 111 fixedly connected to the transmission line GNDs 102 are connected to the conductor plates 103 via the slits 110.

FIG. 11(b) is a side view of the conductor plate substrate viewed in an X to X′ direction of FIG. 11(a). As illustrated in FIG. 11(b), the slits 110 being each a rectangular opening is provided in the upper part and the lower part in a height direction of the conductor plate substrate. Further, the connecting parts 111 that are fixedly connected to the transmission line GNDs 102 are inserted into the slits 110 and connected to the conductor plates 103.

When the conductor plate substrate is moved in the length direction of the current probe at this time, it is slid in a moving direction through the slit 110, and therefore the conductor plate 103 is movable in the length direction. Thereby, when the conductor plate substrate is pressed against other fixed objects before the main body substrate is pressed against the pin during a real measurement, a distance between the loop coil of the main body substrate and a current flowing through the object to be measured becomes large and sensitivity is reduced. In this case, a recessed amount in the concave of the tip of the current probe according to the present embodiment is varied to a suitable length by sliding the conductor plate substrate. As a result, the main body substrate is adjusted so as to be pressed against an object to be measured and detection sensitivity of a current flowing through the object to be measured is improved.

Further, when the conductor plate 103 of the conductor plate substrate and the transmission line GND 102 are connected by using the connecting part 111 using a conductor member, a potential of the conductor plate 103 is the same as that of the transmission line GND 102. Therefore, an unnecessary induced voltage generated on the conductor plate due to potential fluctuations of the pin approximated to the conductor plate 103, namely, a noise component in the magnetic field measurement is reduced.

In the present embodiment, there is used a structure in which the slit is provided as a moving mechanism that is adjustable in the length direction of the current probe; further, not limited thereto, and other moving mechanisms may be used. In addition, a shape or the number of the slits is not limited to the present embodiment.

### Fourth Embodiment

In the present embodiment, there will be described a structure example of the probe that improves a measurement sensitivity to a magnetic field generated by a current flowing through an object to be measured while having a structure in which an influence of an unnecessary magnetic field generated by a current flowing through an object not to be measured adjacent to the object to be measured is reduced.

FIG. 12 illustrates an example of a structure diagram of the current probe according to the present embodiment. In the present embodiment, there is illustrated an example of a structure in which an unnecessary magnetic field generated by a adjacent current to be measured is reduced and sensitivity to a magnetic field generated by a current flowing through the object to be measured is improved. The current probe of the present embodiment includes the conductor plate 103 for canceling an unnecessary magnetic field generated by an adjacent current to be measured. As illustrated in FIG. 12, a magnetic layer that is made of a magnetic material 1000 larger than 1 in permeability is provided at the inside of the conductor plate 103 so as to face the conductor plate 103. Further, the magnetic material 1000 is connected by using a via hole 1001 so that magnetic layers are communicated with each other between the loop coils used as the magnetic field sensor 100.

In this manner, a magnetic field generated by a current flowing through a pin or a harness to be measured is concentrated into a magnetic body, and therefore a magnetic field that is interlinked with the loop coil becomes large. As a result, a voltage induced on the loop coil is enlarged with respect to a current flowing through the same object to be measured. That is, sensitivity to detect a magnetic field is improved. As the magnetic body, ferrite, for example, may be preferably used.

Further, in the case of the printed-circuit board about the current probe, a multilayer structure is used. Magnetic layers are provided on both sides centering on a layer of the magnetic field sensor 100, and conductor plate layers are provided on both sides of the magnetic layers. Further, two magnetic layers may be preferably connected by using a plurality of via holes so as to be inserted into the magnetic field sensor 100, namely, a loop inside of the loop coil.

### Fifth Embodiment

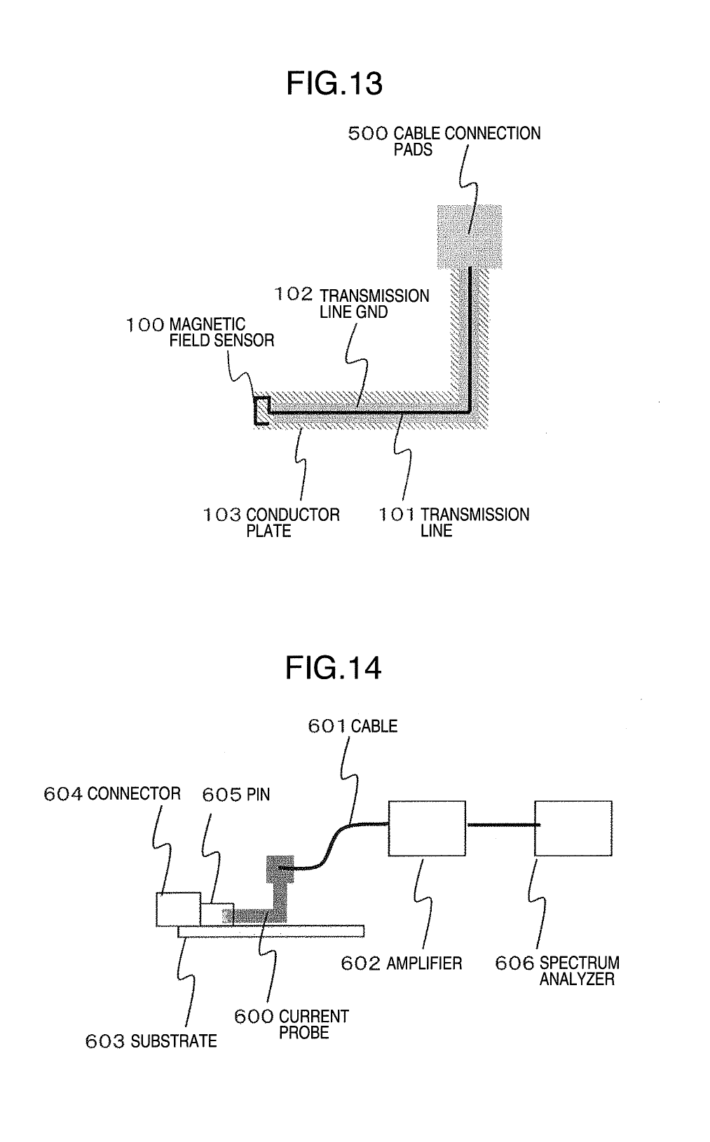

In the present embodiment, there will be described a structure example of the probe having a bent transmission line for easily measuring a current flowing through a connector pin mounted on a substrate of electronic equipment. FIG. 13 illustrates an example of a structure diagram in which the transmission line is bent in the current probe of the present embodiment, and the current probe is configured by using a printed-circuit board. Through a multilayer substrate configuration, the magnetic field sensor 100, the transmission line 101, the transmission line GND 102, the conductor plate 103, and the cable connection pad 500 are formed by using a conductor pattern.

FIG. 14 is a configuration diagram of a measurement system using the current probe of the present invention in which the transmission line is bent. The current probe is connected to the cable 601 in the cable connection pad 500 provided on a rear end of the transmission line 101, and connected to the spectrum analyzer 606 via the amplifier 602.

The measurement system has a structure in which the transmission line 101 is bent as in an example of FIG. 13. Thereby, when the probe is contacted with the pin of the connector mounted on the substrate, a part of the probe is pressed against the substrate to improve simplicity of a measurement.

A bending position of the transmission line or an angle and a shape of bending are not limited to the example of FIG. 13, and may be preferably changed according to a shape of an object to be measured. Further, there is such an advantage that also in the case where position control of the probe is performed by using a machine such as an electromagnetic field exploration apparatus, position control of the probe becomes easy by bending the transmission line.

Heretofore, a structure of the current probe of the present invention is described. In addition, the present invention is not limited to the above-described embodiments, but includes various modifications. For example, the above-described embodiments are described in detail in order to clearly describe the present invention, and are not necessarily limited to the device having all the described constructions. Further, a part of constructions according to one embodiment can be replaced by those according to other embodiment, and the constructions according to other embodiment can be added to that according to one embodiment. Further, an addition, deletion, or replacement of the constructions according to other embodiment can be performed by using a part of the constructions according to each embodiment.

The probe, for example, may be realized by using a semiconductor process used in a silicon integrated circuit. The magnetic field sensor 100 is not limited to a loop coil, and a magnetic field detection element such as a Hall element may be used. An amplifier circuit such as an amplifier may be integrated on a substrate of the current probe. An object to be measured is described by assuming a pin or a harness; further, the current probe is applicable to a circuit on which a plurality of line currents are concentrated, such as a pattern on a substrate. Also, a shape of an object to be measured is not limited to a columnar shape. Further, an example where the conductor plates are arranged at both sides of a portion of the current probe including the magnetic field sensor is illustrated; further, the conductor plate may be arranged not only at one side or right and left sides, but also at the upper part or the lower part of the magnetic field sensor.

### REFERENCE SIGNS LIST

100 Magnetic field sensor
101 Transmission line
102 Transmission line GND
103 Conductor plate
104 Pin to be measured
105 Magnetic field generated by current flowing through pin to be measured
106 Adjacent pin
107 Unnecessary magnetic field
108 Canceling current
109 Canceling magnetic field
110 Slit
111 Connecting part
200 Insulator
500 Cable connection pad
600 Current probe
601 Cable
602 Amplifier
603 Substrate
604 Connector
605 Pin
606 Spectrum analyzer
900 Movable part
1000 Magnetic body
1001 Via hole

1. A current probe comprising:
a sensor that detects a magnetic field;
a transmission line that is connected to the sensor; and
a pair of conductive members that projects to a forward direction from a tip of the sensor and that is provided so as to face the sensor, wherein
a front portion of the sensor, which is surrounded by a projecting portion of the conductive members, is opened in a direction of a plane that faces the conductive members.

2. The current probe according to claim 1, wherein
a tip of the current probe has a concave shape.

3. The current probe according to claim 1, wherein
the sensor includes a coiled loop conductor.

4. The current probe according to claim 1, wherein
the sensor includes a Hall element.

5. The current probe according to claim 1, wherein
a GND conductor that covers the transmission line is provided, and the GND conductor and the conductive member are connected each other.

6. The current probe according to claim 1, wherein
between an object to be measured and an object not to be measured generating an unnecessary magnetic field, one projecting portion near to the object not to be measured in the pair of conductive members is provided so as to be arranged.

7. The current probe according to claim 1, wherein
the conductive member is arranged and provided so as to reduce that an unnecessary magnetic field of the object not to be measured generating an unnecessary magnetic field is interlinked with the sensor.

8. The current probe according to claim 1, wherein
a gap distance adjustment mechanism capable of adjusting a gap distance between the sensor and the plate-like member is provided.

9. The current probe according to claim 8, wherein
the gap distance adjustment mechanism includes an elastic body member.

10. The current probe according to claim 1, wherein
a projecting amount adjustment mechanism capable of adjusting a projecting amount of the plate-like member that projects to a forward direction from a tip of the sensor is provided.

11. The current probe according to claim 10, further comprising a substrate including the plate-like member, wherein
the projecting amount adjustment mechanism is, when the substrate is moved through a slit provided on the substrate, a mechanism capable of adjusting a projecting amount of the conductor plate.

12. The current probe according to claim 1, wherein
a layer of an elastic body is provided between the sensor and the plate-like member, and the elastic body is provided so as to pass through a magnetic field detection section of the sensor.

13. The current probe according to claim 1, further comprising a structure in which the transmission line is bent.

14. A current probe comprising:
a sensor that detects a magnetic field;
a transmission line that is connected to the sensor; and
a pair of conductive members that projects to a direction of a side opposite to a connection side to the transmission line of the sensor from a tip of the sensor and that is provided so as to face the sensor, wherein
a forward portion of the sensor, which is surrounded by a projecting portion of the conductive members, is opened in a direction of a plane that faces the conductive members.

15. A current probe measurement system comprising:
a current probe including:
a sensor that detects a magnetic field;
a transmission line that is connected to the sensor; and
a pair of conductive members that projects to a forward direction from a tip of the sensor and that is provided so as to face the sensor, wherein
a front portion of the sensor, which is surrounded by a projecting portion of the conductive members, is opened in a direction of a plane that faces the conductive members;
a cable connection pad that is provided on a rear end of the transmission line of the current probe;
a cable that is connected to the cable connection pad and that is connected to a measurement instrument; and
a measurement instrument that is connected to the current probe through the cable and that measures an induced voltage detected by the current probe.

16. A current probe measurement method comprising:
by a current probe including:
a sensor that detects a magnetic field;
a transmission line that is connected to the sensor; and
a pair of conductive members that projects to a forward direction from a tip of the sensor and that is provided so as to face the sensor, wherein
a front portion of the sensor, which is surrounded by a projecting portion of the conductive members, is opened in a direction of a plane that faces the conductive members, inserting and measuring an object to be measured between facing projecting portions of the pair of conductive members.
